(19) United States
(12) Patent Application Publication
(10) Pub. No.: US 2023/0115948 A1
(43) Pub. Date: Apr. 13, 2023

(54) ARRAY SUBSTRATE, DISPLAY PANEL, DISPLAY DEVICE AND MANUFACTURING METHOD

(71) Applicant: BOE Technology Group Co., Ltd., Beijing (CN)

(72) Inventors: Pan XU, Beijing (CN); Yongqian LI, Beijing (CN); Yicheng LIN, Beijing (CN); Ling WANG, Beijing (CN); Guoying WANG, Beijing (CN); Xing ZHANG, Beijing (CN); Ying HAN, Beijing (CN); Dacheng ZHANG, Beijing (CN); Lang LIU, Beijing (CN); Chen XU, Beijing (CN)

(21) Appl. No.: 17/914,929

(22) PCT Filed: Feb. 2, 2021
(86) PCT No.: PCT/CN2021/074949

§ 371 Date: Sep. 27, 2022

(30) Foreign Application Priority Data
Mar. 31, 2020 (CN) 202010242660.6

(51) Int. Cl. H10K 59/126; H10K 71/00

(52) U.S. Cl. CPC H01L 27/3272; H01L 51/56; H01L 2227/323

(57) ABSTRACT

The present disclosure provides an array substrate, a display panel, a display device and a manufacturing method, for solving the problems in the prior art that the array substrate is larger in number of circuits, the area needed for punching is larger, and the high pixel resolution cannot be achieved easily. The array substrate comprises: an interlayer dielectric layer located at the side of the active layer distant from the buffer layer, the interlayer dielectric layer being provided with a via hole, the via hole comprising a first part and a second part, the orthographic projection of the first part on the base substrate being in contact with the orthographic projection of the second part on the base substrate, the first part of the via hole penetrating through the interlayer dielectric layer and the buffer layer and exposing part of the shading layer, and the second part penetrating through the interlayer dielectric layer and exposing at least part of the active layer; and a source/drain layer located at the side of the interlayer dielectric layer distant from the active layer.

### CROSS REFERENCE TO RELATED APPLICATIONS

The present application is a US National Stage of International Application No. PCT/CN2021/074949, filed on Feb. 2, 2021, which claims priority to Chinese patent application No. 202010242660.6 filed on Mar. 31, 2020 to the China Patent Office, and entitled “ARRAY SUBSTRATE, DISPLAY PANEL, DISPLAY DEVICE AND MANUFACTURING METHOD”, the entire content of which is incorporated herein by reference.

### FIELD

The present disclosure relates to the technical field of display, in particular to an array substrate, a display panel, a display apparatus and a manufacturing method.

### BACKGROUND

Among novel display apparatuses appearing in the market at present, active-matrix organic light-emitting diodes (AMOLED) are one of the hottest products. The market is in great demand for AMOLED displays. As small as mobile phone screens, and as large as oversized TV series. The oversized TV series mainly use white-light OLED (WOLED) bottom emitting structures, where a relatively mature technology is an oxide top gate technology.

The most mature technological process in the oxide top gate technology is: light shielding layer (LS)→active layer (Active)→gate layer (GI&GT)→interlayer dielectric layer (CNT&ILD)→source drain layer (SD)→metal wire protecting layer (PVX)→planarization layer (PLN)→OLED anode layer (ITO)→pixel defining layer (PDL). A manufacturing process needs to include a technology that LS is connected with the Active layer through the SD layer. However, in the related art, when the LS layer is connected with the Active layer, a large region for punching is required, and due to many circuits of an AMOLED array substrate itself, the large region for punching is disadvantageous to implementation of high pixels per inch (PPI) of the AMOLED.

### SUMMARY

An embodiment of the present disclosure provides an array substrate, including: a base substrate; a light shielding layer, located on a side of the base substrate; a buffer layer, located on a side of the light shielding layer facing away from the base substrate; an active layer, located on a side of the buffer layer facing away from the light shielding layer, an orthographic projection of the active layer on the base substrate being covered by an orthographic projection of the light shielding layer on the base substrate; an interlayer dielectric layer, located on a side of the active layer facing away from the buffer layer, the interlayer dielectric layer having a via hole, the via hole including a first part and a second part, an orthographic projection of the first part on the base substrate being in contact with an orthographic projection of the second part on the base substrate, the first part of the via hole penetrating through the interlayer dielectric layer and the buffer layer and exposing a part of the light shielding layer, and the second part of the via hole penetrating through the interlayer dielectric layer and exposing at least a part of the active layer; and a source drain layer, located on a side of the interlayer dielectric layer facing away from the active layer, the source drain layer being electrically connected with the light shielding layer through the first part, and being electrically connected with the active layer through the second part.

In a possible implementation, the interlayer dielectric layer has a step structure on a side wall facing the first part, and an orthographic projection of the step structure on the base substrate is a semi-closed frame pattern.

In a possible implementation, a center of the orthographic projection of the step structure on the base substrate does not overlap a center of a first region, and the first region is a region of the light shielding layer exposed by the first part.

In a possible implementation, the step structure includes: a first inclined surface connected with a surface of the interlayer dielectric layer facing away from the buffer layer, a second inclined surface connected with a surface of the interlayer dielectric layer facing the buffer layer, and a plane connecting the first inclined surface with the second inclined surface; and the buffer layer has a third inclined surface on a side wall facing the first part; and the second inclined surface and the third inclined surface are located on a same inclined surface.

In a possible implementation, the orthographic projection of the active layer on the base substrate is in contact with the orthographic projection of the first part on the base substrate.

In a possible implementation, the orthographic projection of the active layer on the base substrate and the orthographic projection of the first part on the base substrate have a gap therebetween.

In a possible implementation, a material of the active layer includes a semiconductor oxide.

In a possible implementation, a depth of the via hole at a position exposing the light shielding layer is 5000 Å to 16000 Å.

In a possible implementation, a depth of the via hole at a position exposing the active layer is 4000 Å to 12000 Å.

In a possible implementation, an angle of gradient of the via hole is 40° to 80°.

In a possible implementation, the array substrate includes a driving transistor, and the source drain layer is a source drain layer of the driving transistor.

In a possible implementation, a material of the light shielding layer is metal.

An embodiment of the present disclosure further provides a display panel, including the array substrate provided by the embodiment of the present disclosure.

An embodiment of the present disclosure further provides a display apparatus, including the display panel provided by the embodiment of the present disclosure.

An embodiment of the present disclosure further provides a manufacturing method of an array substrate, including: forming a light shielding layer on a side of a base substrate; forming a buffer layer on a side of the light shielding layer facing away from the base substrate; forming an active layer on a side of the buffer layer facing away from the light shielding layer; forming an interlayer dielectric layer on a side of the active layer facing away from the buffer layer; by punching on a side of the interlayer dielectric layer facing away from the active layer, forming a first part of a via hole penetrating through the interlayer dielectric layer and the buffer layer and exposing a part of the light shielding layer, and forming a second part of the via hole penetrating through the interlayer dielectric layer and exposing at least a part of the active layer, an orthographic projection of the first part on the base substrate being in contact with an orthographic projection of the second part on the base substrate; and forming a source drain layer on a side of the interlayer dielectric layer facing away from the active layer, the source drain layer covering the via hole, being electrically connected with the light shielding layer through the first part, and being electrically connected with the active layer through the second part.

In a possible implementation, the, by punching on a side of the interlayer dielectric layer facing away from the active layer, forming a first part of a via hole penetrating through the interlayer dielectric layer and the buffer layer and exposing a part of the light shielding layer, and forming a second part of the via hole penetrating through the interlayer dielectric layer and exposing at least a part of the active layer, include: etching a portion of the interlayer dielectric layer not overlapping a region where the active layer is located to form a groove, wherein an orthographic projection of the groove on the base substrate does not overlap an orthographic projection of the active layer on the base substrate; and continuing to etch a region of the interlayer dielectric layer where the groove is located and the buffer layer to expose a part of the light shielding layer, and etching a part of the interlayer dielectric layer other than the region of the groove to expose at least a part of the active layer so as to form a through groove, wherein an orthographic projection of the through groove on the base substrate covers an orthographic projection of a part of the active layer on the base substrate and covers an orthographic projection of a part of the light shielding layer on the base substrate, and the through groove and the groove overlap at a region where the light shielding layer is located to form a sleeved hole.

In a possible implementation, the continuing to etch a region of the interlayer dielectric layer where the groove is located and the buffer layer to expose a part of the light shielding layer, and etching a part of the interlayer dielectric layer other than the region of the groove to expose at least a part of the active layer so as to form a through groove, includes: continuing to etch the region of the interlayer dielectric layer where the groove is located and the buffer layer to expose a part of the light shielding layer so as to form a second sub-through groove, and etching the part of the interlayer dielectric layer other than the region of the groove to expose at least a part of the active layer to form a first sub-through groove, wherein the first sub-through groove and the second sub-through groove are connected, and an orthographic projection of the second sub-through groove on the base substrate is covered by the orthographic projection of the groove on the base substrate.

In a possible implementation, the etching a portion of the interlayer dielectric layer not overlapping a region where the active layer is located, includes: etching the portion of the interlayer dielectric layer not overlapping the region where the active layer is located, and controlling an etching depth to be equal to a first thickness, wherein the first thickness is a sum of a thickness of the buffer layer at a position of the light shielding layer and a thickness of the active layer.

In a possible implementation, the orthographic projection of the groove on the base substrate and the orthographic projection of the active layer on the base substrate have a gap.

In a possible implementation, the orthographic projection of the groove on the base substrate is in contact with the orthographic projection of the active layer on the base substrate.

### BRIEF DESCRIPTION OF THE DRAWINGS

FIG. 1 is a schematic sectional view of an array substrate with an active layer and a light shielding layer connected in the related art.

FIG. 2 is a schematic top view corresponding to FIG. 1.

FIG. 3A is a schematic structural diagram of an array substrate provided by an embodiment of the present disclosure.

FIG. 3B is a schematic top view of a light shielding portion provided by an embodiment of the present disclosure.

FIG. 4A is a schematic sectional view of an array substrate with a step structure provided by an embodiment of the present disclosure.

FIG. 4B is a schematic top view of an array substrate with a step structure provided by an embodiment of the present disclosure.

FIG. 4C is a schematic structural diagram of an array substrate with a gap between an active layer and a first part provided by an embodiment of the present disclosure.

FIG. 5A is a schematic top view of a via hole including a groove and a through groove.

FIG. 5B is a schematic top view corresponding to FIG. 5A.

FIG. 6 is a specific schematic structural diagram of a through groove provided by an embodiment of the present disclosure.

FIG. 7 is a schematic top view corresponding to FIG. 6.

FIG. 8 is a diagram of a manufacturing flow of an array substrate provided by an embodiment of the present disclosure.

FIG. 9A is a schematic sectional view of an array substrate with a manufactured light shielding layer provided by an embodiment of the present disclosure.

FIG. 9B is a schematic top view of an array substrate with a manufactured light shielding layer provided by an embodiment of the present disclosure.

FIG. 10A is a schematic sectional view of an array substrate with a manufactured active layer provided by an embodiment of the present disclosure.

FIG. 10B is a schematic top view of an array substrate with a manufactured active layer provided by an embodiment of the present disclosure.

FIG. 11 is a schematic sectional view of an array substrate with a manufactured interlayer dielectric layer provided by an embodiment of the present disclosure.

FIG. 12A is a schematic sectional view of an array substrate with a manufactured groove.

FIG. 12B is a schematic top view of an array substrate with a manufactured groove.

FIG. 13A is a schematic sectional view of an array substrate with a manufactured through groove provided by an embodiment of the present disclosure.

FIG. 13B is a schematic top view of an array substrate with a manufactured through groove provided by an embodiment of the present disclosure.

FIG. 14A is a schematic sectional view of an array substrate with a manufactured source drain layer provided by an embodiment of the present disclosure.

FIG. 14B is a schematic top view of an array substrate with a manufactured source drain layer provided by an embodiment of the present disclosure.

### DETAILED DESCRIPTION OF THE EMBODIMENTS

In order to make the objectives, technical solutions and advantages of embodiments of the present disclosure clearer, the technical solutions of the embodiments of the present disclosure will be clearly and completely described below in conjunction with the accompanying drawings of the embodiments of the present disclosure. Apparently, the described embodiments are only a part of the embodiments of the present disclosure, not all of the embodiments. Based on the described embodiments of the present disclosure, all other embodiments obtained by those of ordinary skill in the art without creative work shall fall within the protection scope of the present disclosure.

Unless otherwise defined, technical or scientific terms used in the present disclosure shall have the ordinary meanings understood by those ordinarily skilled in the art to which the present disclosure pertains. The words “first”, “second” and the like used in the present disclosure do not indicate any order, quantity or importance, but are only configured to distinguish different components. The words “comprise” or “include” or the like indicate that an element or item appearing before such words covers listed elements or items appearing after the words and equivalents thereof, and does not exclude other elements or items. The words “connect” or “couple” or the like are not limited to physical or mechanical connection, but may include electrical connection, whether direct or indirect. “Upper”, “lower”, “left”, “right” and the like are only used to represent relative position relationships, and the relative position relationships may also change accordingly after an absolute position of a described object is changed.

In order to keep the following descriptions of the embodiments of the present disclosure clear and concise, detailed descriptions of known functions and known components are omitted.

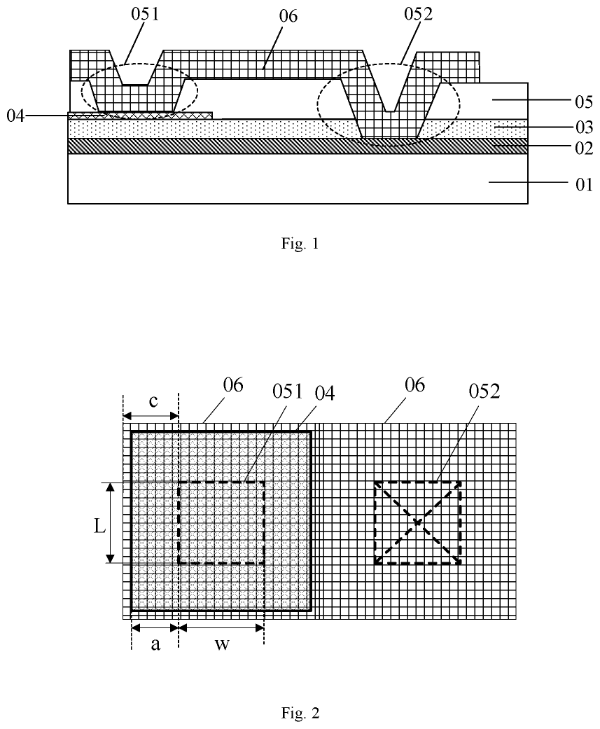

In a traditional technology, there are certain rules for designing a via hole, in combination with FIGS. 1-2, an array substrate includes a light shielding layer 02, a buffer layer 03, an active layer 04, an interlayer dielectric layer 05 and a source drain layer 06 located on a base substrate 01 in sequence, wherein the active layer 04 and the light shielding layer 02 are connected through the source drain layer 06 via two via holes. Each via hole has a minimum size rule, taking FIGS. 1 and 2 as an example, for example, W and L are the minimum width and length of the via hole. a is a distance by which a pattern of the active layer 04 (Active) is greater than an interlayer dielectric layer hole 051 (ILD hole) (that is, after manufacturing, an orthographic projection of the active layer 04 on the base substrate is to cover an orthographic projection of the interlayer dielectric layer hole 051 on the base substrate), c is a distance by which a pattern of the source drain layer 06 is greater than the interlayer dielectric layer hole 051 (ILD hole), and specific a, c, W and L are jointly decided by an exposure alignment deviation (Overlap) between layers, a dimensional uniformity deviation (Torrance) during exposure and a dimensional variation (Bias) during etching.

The above values are decided by devices and process capability, and thus these basic rules must be met during design. When the light shielding layer and the active layer are connected in the traditional technology, mainly two manners are used.

As shown in FIGS. 1 and 2, the two via holes include the interlayer dielectric layer via hole 051 (ILD via hole) and a connecting hole 052 (CNT via hole); after the interlayer dielectric layer 05 is deposited, the connecting hole 052 (CNT via hole) is manufactured first, and the connecting hole 052 (CNT via hole) needs to etch the interlayer dielectric layer 05 and the buffer layer 03 to achieve lap-joint of the source drain layer 06 and the light shielding layer 02; and then, the interlayer dielectric layer via hole 051 (ILD via hole) is manufactured, and the interlayer dielectric layer via hole 051 (ILD via hole) needs to etch the interlayer dielectric layer 05 to achieve lap-joint of the source drain layer 06 and the active layer 04.

It can be known from the above that at least two via holes are required for connection of the active layer 04 and the light shielding layer 02. To achieve lap-joint, a space which is required at least is of the size of the two via holes and the exposure alignment deviation (Overlap) of the active layer 04, the light shielding layer 02 and the source drain layer 06 with the via holes. An occupied area is larger, which is not conductive to the pixel design of high PPI.

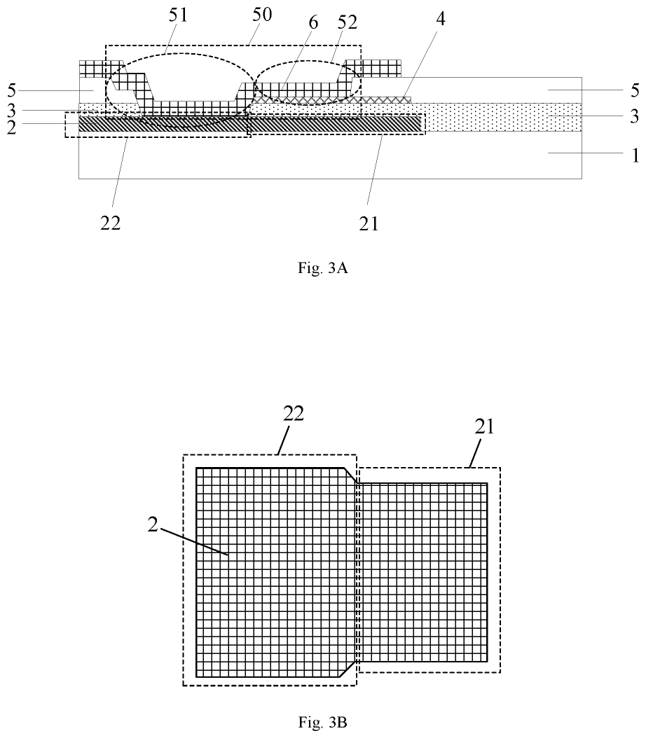

Based on this, referring to FIG. 3A, an embodiment of the present disclosure provides an array substrate, including: a base substrate 1; a light shielding layer 2, wherein the light shielding layer 2 is located on one side of the base substrate 1, a material of the light shielding layer 2 may specifically be metal (specifically, molybdenum Mo, molybdenum-niobium MoNb or molybdenum-aluminum MoAl) to shade an active layer 4, and the light shielding layer 2 may specifically include a first light shielding portion 21 and a second light shielding portion 22 other than the first light shielding portion 21, that is, in combination with FIG. 3B, the region other than the first light shielding portion 21 in the light shielding layer 2 may be the second light shielding portion 22, wherein an orthographic projection of the first light shielding portion 21 on the base substrate 1 may overlap an orthographic projection of the active layer 4 on the base substrate 1; a buffer layer 3, located on a side of the light shielding layer 2 facing away from the base substrate 1; the active layer 4, the active layer 4 being located on a side of the buffer layer 3 facing away from the light shielding layer 2, an orthographic projection of the active layer 4 on the base substrate 1 being covered by an orthographic projection of the light shielding layer 2 on the base substrate 1, and a material of the active layer 4 being specifically an oxide semiconductor; an interlayer dielectric layer 5, the interlayer dielectric layer 5 being located on a side of the active layer 4 facing away from the buffer layer 3, the interlayer dielectric layer 5 having a via hole 50, the via hole 50 including a first part 51 and a second part 52, an orthographic projection of the first part 51 on the base substrate 1 being in contact with an orthographic projection of the second part 52 on the base substrate 1, the first part 51 penetrating through the interlayer dielectric layer 5 and the buffer layer 3 and exposing a part of the light shielding layer 2, and the second part 52 penetrating through the interlayer dielectric layer 5 and exposing at least a part of the active layer 4; and a source drain layer 6, the source drain layer 6 being located on a side of the interlayer dielectric layer 5 facing away from the active layer 4, and the source drain layer 6 being electrically connected with the light shielding layer 2 through the first part 51, and being electrically connected with the active layer 4 through the second part 52, wherein the source drain layer 6 may specifically include a source electrode and a drain electrode, and specifically, the source electrode may be electrically connected with the active layer 4 and the light shielding layer 2 through the via hole.

The array substrate provided by the embodiment of the present disclosure includes: the base substrate; the light shielding layer, the buffer layer, the active layer and the interlayer dielectric layer, the interlayer dielectric layer has the via hole, the first part of the via hole penetrates through the interlayer dielectric layer and the buffer layer and exposes a part of the light shielding layer, the second part of the via hole penetrates through the interlayer dielectric layer and exposes at least a part of the active layer, and the source drain layer is electrically connected with the active layer and the light shielding layer through the via hole, that is, by arranging one via hole, while exposing the light shielding layer, the via hole further exposes the active layer, and finally the light shielding layer and the active layer may be connected through the source drain layer via the via hole. Compared with the related art that when the light shielding layer and the active layer are connected through the two independent via holes, since each via hole has a minimum dimension limit and a certain distance is required between the two via holes, a large region for punching is required when the light shielding layer and the active layer are connected, according to the connecting manner provided by the embodiment of the present disclosure, the light shielding layer and the active layer may be connected through one via hole, and in the case that the via hole needs the same minimum dimension, in the embodiment of the present disclosure, a region required for connecting the active layer and the light shielding layer is smaller, thereby solving the problems in the related art that an array substrate is larger in number of circuits, a region needed for punching is larger, and a high pixel resolution cannot be achieved easily.

During specific implementation, the array substrate in the embodiment of the present disclosure may be specifically an AMOLED array substrate. In general, the array substrate may include a driving transistor and a switching transistor, and the source drain layer, the active layer and the light shielding layer in the embodiment of the present disclosure may be specifically a source drain layer, an active layer and a light shielding layer of a driving transistor on the AMOLED array substrate, that is, the light shielding layer and the active layer at corresponding positions of the driving transistor are electrically connected through a source of the driving transistor. It can be understood that the material of the light shielding layer is generally metal, while in a driving process of the array substrate, an appropriate potential generally needs to be loaded to the light shielding layer of the metal material to avoid the situation that the normal driving process of the array substrate is affected due to the fact that the light shielding layer forms coupling capacitance with other electrodes, and the connection of the light shielding layer and the source may avoid other additional influence on transistors while avoiding the influence of the light shielding layer on the driving process by the existence of the coupling capacitance.

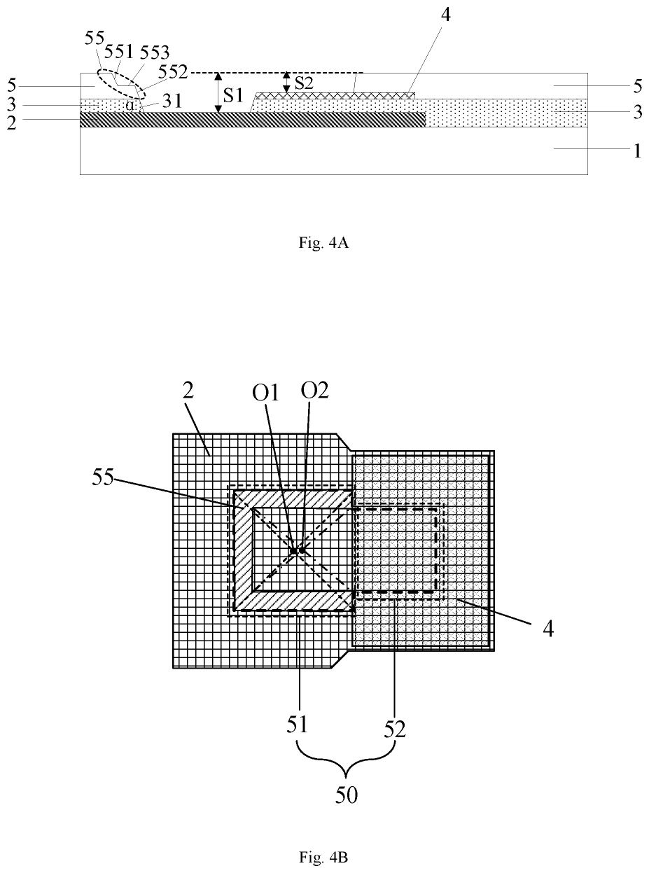

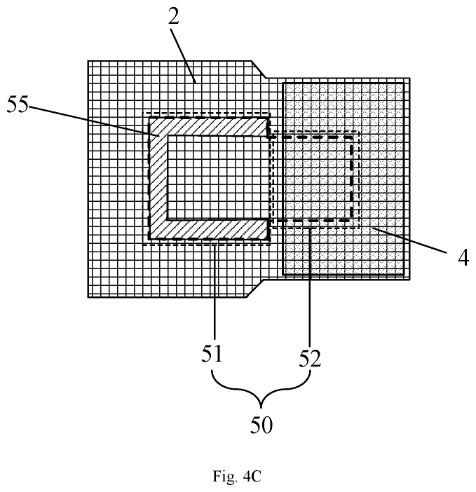

During specific implementation, referring to FIG. 4A and FIG. 4B, the interlayer dielectric layer 5 has a step structure 55 on a side wall facing the first part 51, and an orthographic projection of the step structure 55 on the base substrate 1 is a semi-closed frame pattern (e.g., an oblique-line region in FIG. 4B). In the embodiment of the present disclosure, the interlayer dielectric layer 5 has the step structure 55 on the side wall facing the first part 51, that is, when the via hole is manufactured, the step structure 55 may be formed in the middle of the interlayer dielectric layer 5 in the thickness direction, so that when the source drain layer 6 above the interlayer dielectric layer 5 is in lap joint with the light shielding layer 2 through the interlayer dielectric layer 5 and the buffer layer 3, a large covering region exists at the step structure 55, thereby avoiding the problems that when the source drain layer 6 directly extends to the light shielding layer 2 from an upper surface of the interlayer dielectric layer 5, a segment gap is large, the defect of line breakage of the source drain layer 6 is prone to occurring, and consequently the source drain layer 6 and the light shielding layer 2 are not good in lap-joint.

During specific implementation, in combination with FIG. 4B, a center 01 of an orthographic projection of the step structure 55 on the base substrate 1 does not overlap a center 02 of a first region. The first region is a region of the light shielding layer 2 exposed by the first part 51, that is, the first region is a region belonging to the light shielding layer 2 and exposed by the first part 51 (i.e., the light shielding layer 2 surrounded by the step structure 55 in FIG. 4B). In the embodiment of the present disclosure, since a right boundary (i.e., an opening of the step structure 55) of the step structure 55 in FIG. 4B and a right boundary of the first region overlap, namely being the same line segment, the center 01 of the orthographic projection of the step structure 55 on the base substrate 1 does not overlap the center 02 of the first region, thereby avoiding the problems that if the two centers are required to completely overlap, high technology manufacturing precision is required, it is too difficult to manufacture the via hole meeting the requirement, and the manufacturing yield is low. Of course, if the difficulty of a manufacturing technology is not considered, the center 01 of the orthographic projection of the step structure 55 on the base substrate 1 and the center 02 of the first region may also overlap.

Specifically, in combination with FIG. 4A, the step structure 55 includes: a first inclined surface 551 connected with a surface of the interlayer dielectric layer 5 facing away from the buffer layer 3, a second inclined surface 552 connected with a surface of the interlayer dielectric layer 5 facing the buffer layer 3, and a plane 553 connecting the first inclined surface 551 with the second inclined surface 552. The buffer layer 3 has a third inclined surface 31 on a side wall facing the first part 51, and the second inclined surface 552 and the third inclined surface 31 are located on the same inclined surface.

During specific implementation, an orthographic projection of the active layer 4 on the base substrate 1 and an orthographic projection of the first part 51 on the base substrate 1 may be in contact with each other or may have a certain distance therebetween, that is, in combination with FIG. 4B, the orthographic projection of the active layer 4 on the base substrate 1 is in contact with the orthographic projection of the first part 51 on the base substrate; or, in combination with FIG. 4C, the orthographic projection of the active layer 4 on the base substrate 1 and the orthographic projection of the first part 51 on the base substrate 1 have a gap therebetween.

During specific implementation, a material of the active layer 4 includes a semiconductor oxide. Specifically, for example, the material may be an indium gallium zinc oxide (IGZO) or an indium-doped zinc oxide (IZO).

During specific implementation, in combination with FIG. 4A, a depth 51 of the via hole 50 at a position exposing the light shielding layer 2 is 5000 Å to 16000 Å. A depth of the via hole 50 at a position exposing the active layer 4 is 4000 Å to 12000 Å. In general, a film thickness of the interlayer dielectric layer 5 is 4000 Å to 12000 Å, and a thickness of the buffer layer 3 is 1000 Å to 4000 Å, so that in the embodiment of the present disclosure, the depth 51 of the via hole 50 at the position exposing the light shielding layer 2 may be set to be 5000 Å (i.e., the sum of the minimum thickness 4000 Å of the interlayer dielectric layer 5 and the minimum thickness 1000 Å of the buffer layer 3) to 16000 Å (i.e., the sum of the maximum thickness 12000 Å of the interlayer dielectric layer 5 and the maximum thickness 4000 Å of the buffer layer 3). Accordingly, the depth of the via hole 50 at the position exposing the active layer 4 may be 4000 Å to 12000 Å, namely being equal to the thickness of the interlayer dielectric layer 5.

During specific implementation, referring to FIG. 4A, an angle of gradient a of the via hole 50 may be 40° to 80°.

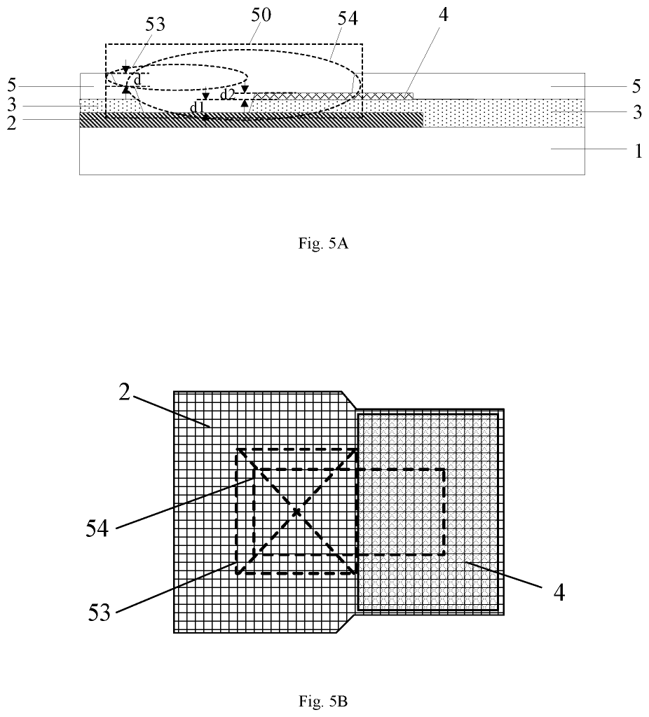

During specific implementation, referring to FIG. 5A and FIG. 5B, the via hole 50 may include: a groove 53 and a through groove 54. An orthographic projection of the groove 53 on the base substrate 1 does not overlap the orthographic projection of the active layer 4 on the base substrate 1, an orthographic projection of the through groove 54 on the base substrate 1 covers a part of the orthographic projection of the active layer 4 on the base substrate 1 and covers a part of the orthographic projection of the light shielding layer 2 on the base substrate 1, and the through groove 54 and the groove 53 overlap at the region where the light shielding layer 2 is located to form a sleeved hole, that is, the groove 53 is located at a position which is in the region where the light shielding layer 2 is located and does not overlap the active layer 4, the through groove 54 is located at the region where the light shielding layer 2 is located and a region where the active layer 4 is located, and the groove 53 and the through groove 54 form the via hole. In the embodiment of the present disclosure, the via hole includes the groove 53 and the through groove 54. When the via hole is specifically manufactured, the via hole may be formed through two times of etching. That is, the interlayer dielectric layer 5 of a certain thickness is etched at a position not overlapping the active layer 4 through a first-time photoetching technology first to form the groove 53, and then the position of the groove 53 and the position of the active layer 4 are etched through a second-time photoetching technology to form the through groove 54 exposing the light shielding layer 2 and the active layer 4. That is, the situation that it is difficult to complete through etching once due to the large total thickness of the interlayer dielectric layer 5 and the buffer layer 3 may be avoided, and moreover, due to the fact that the via hole is different in depth at different positions, the characteristic that the via hole of the present disclosure is different in depth at different positions may be achieved through two times of etching.

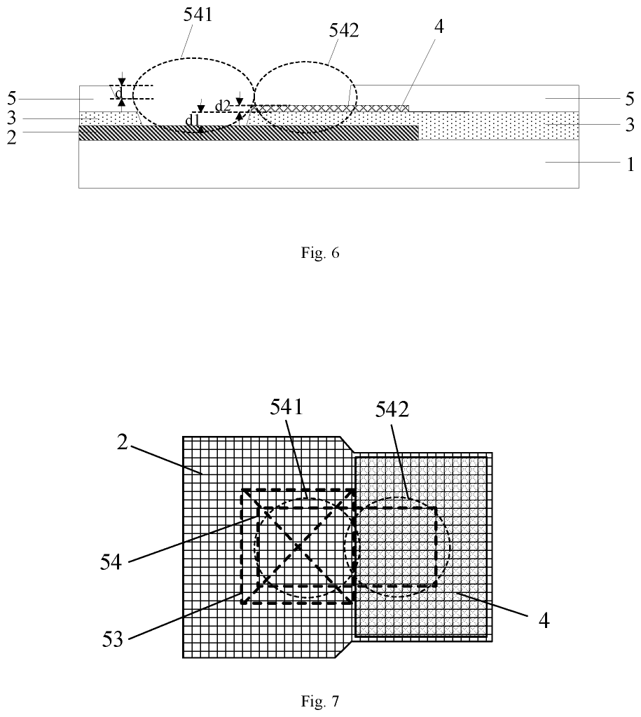

During specific implementation, referring to FIG. 6 and FIG. 7, the through groove 54 may include a first sub-through groove 541 located at the region where the active layer 4 is located and a second sub-through groove 542 connected with the first sub-through groove 541, and an orthographic projection of the first sub-through groove 541 on the base substrate 1 is covered by the orthographic projection of the groove 53 on the base substrate 1. The first sub-through groove 541 may expose the light shielding layer 2, the second sub-through groove 542 may expose the active layer 4, and the first sub-through groove 541 and the second sub-through groove 542 are connected and communicated with each other in a direction parallel to the base substrate 1. In the embodiment of the present disclosure, the through groove 54 may include the first sub-through groove 541 and the second sub-through groove 542, and the orthographic projection of the groove 53 on the base substrate 1 covers the orthographic projection of the first sub-through groove 541 on the base substrate 1. That is, the through groove 54 at a region where the active layer 4 is not located is smaller than the groove 53, the two grooves form the sleeved hole, the opening size of the groove 53 at the sleeved hole is larger than the opening size of the first sub-through groove 541, and in combination with FIG. 3A, FIG. 5A and FIG. 6, a gradient (i.e., the step structure 55) may be formed in the middle of the interlayer dielectric layer 5 in the thickness direction, so that when the source drain layer 6 above the interlayer dielectric layer 5 is in lap joint with the light shielding layer 2 through the interlayer dielectric layer 5 and the buffer layer 3, a large covering region exists at the groove 53, thereby avoiding the problems that if the opening size of the groove 53 is the same as the opening size of the first sub-through groove 541, when the source drain layer 6 directly extends to the light shielding layer 2 from the upper surface of the interlayer dielectric layer 5, the segment gap is large, the defect of line breakage of the source drain layer 6 is prone to occurring, and consequently the source drain layer 6 and the light shielding layer 2 are not good in lap-joint.

During specific implementation, in combination with FIG. 5A, a depth d of the groove 53 is less than the own film layer thickness of the interlayer dielectric layer 5. Specifically, the depth d of the groove 53 is equal to a first thickness, wherein the first thickness is the sum of a thickness d1 of the buffer layer 3 at the position of the light shielding layer 2 and a thickness d2 of the active layer 4, namely d=d1+d2. In the embodiment of the present disclosure, the depth d of the groove 53 is equal to the first thickness, wherein the first thickness is the sum of the thickness of the buffer layer 3 at the position of the light shielding layer 2 and the thickness of the active layer 4, so that during the second time of etching, when etching is performed to the light shielding layer 2 from the position of the first sub-through groove 541, etching may be performed to the active layer 4 from the position of the second sub-through groove 542, and the through groove 54 exposing the different film layers is formed through one time of etching.

During specific implementation, the orthographic projection of the groove 53 on the base substrate 1 and the orthographic projection of the active layer 4 on the base substrate 1 may have a gap. Alternatively, in combination with FIG. 5B, the orthographic projection of the groove 53 on the base substrate 1 may also be in contact with the orthographic projection of the active layer 4 on the base substrate 1. In the embodiment of the present disclosure, the orthographic projection of the groove 53 on the base substrate 1 is in contact with the orthographic projection of the active layer 4 on the base substrate 1, so that while the region required for punching is the minimum, the source has a large contact area with the active layer 4 and the light shielding layer 2, and the conducting effect is good.

During specific implementation, referring to FIG. 5B, the orthographic projection of the groove 53 on the base substrate 1 is a square. The orthographic projection of the through groove 54 on the base substrate 1 is a rectangle. During specific implementation, considering the difference between technologies, it may be difficult to make the orthographic projection of the groove 53 on the base substrate 1 be a complete and regular square, that is, the orthographic projection of the groove 53 on the base substrate 1 being the square in the embodiment of the present disclosure may also mean that the orthographic projection of the groove 53 on the base substrate 1 is similar to a square, and similarly, the orthographic projection of the through groove 54 on the base substrate 1 may also be similar to a rectangle.

Based on the same disclosure concept, an embodiment of the present disclosure further provides a display panel, including the array substrate provided by the embodiment of the present disclosure.

Based on the same disclosure concept, an embodiment of the present disclosure further provides a display apparatus, including the display panel provided by the embodiment of the present disclosure.

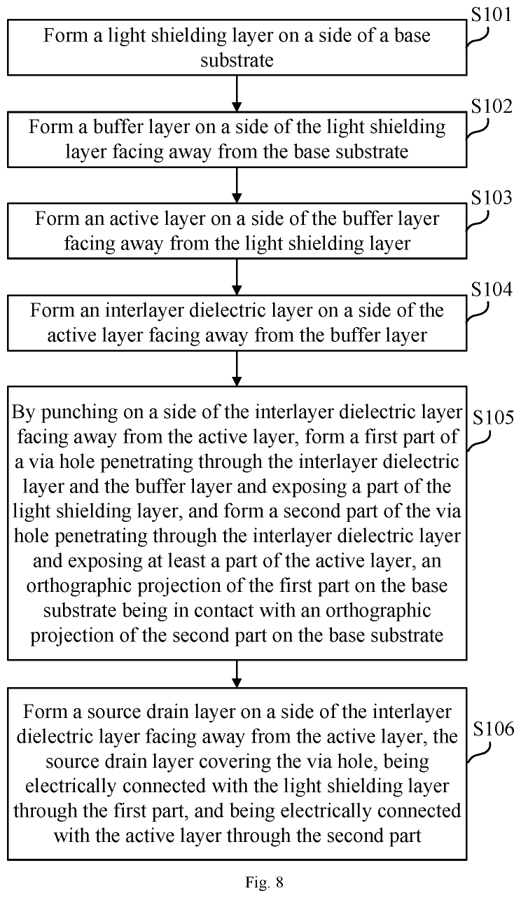

Based on the same disclosure concept, an embodiment of the present disclosure further provides a manufacturing method of an array substrate, referring to FIG. 8, the manufacturing method may be used for manufacturing the array substrate provided by the embodiment of the present disclosure, and the manufacturing method may include the following steps.

S101, a light shielding layer is formed on a side of a base substrate.

S102, a buffer layer is formed on a side of the light shielding layer facing away from the base substrate.

S103, an active layer is formed on a side of the buffer layer facing away from the light shielding layer.

S104, an interlayer dielectric layer is formed on a side of the active layer facing away from the buffer layer.

S105, by punching on a side of the interlayer dielectric layer facing away from the active layer, a first part of a via hole penetrating through the interlayer dielectric layer and the buffer layer and exposing a part of the light shielding layer is formed, and a second part of the via hole penetrating through the interlayer dielectric layer and exposing at least a part of the active layer is formed, an orthographic projection of the first part on the base substrate being in contact with an orthographic projection of the second part on the base substrate.

S106, a source drain layer is formed on a side of the interlayer dielectric layer facing away from the active layer, the source drain layer covering the via hole, being electrically connected with the light shielding layer through the first part, and being electrically connected with the active layer through the second part.

During specific implementation, S105 that, by punching on a side of the interlayer dielectric layer facing away from the active layer, the first part of the via hole penetrating through the interlayer dielectric layer and the buffer layer and exposing a part of the light shielding layer is formed, and the second part of the via hole penetrating through the interlayer dielectric layer and exposing at least a part of the active layer is formed, includes S1051 and S1052.

S1051, a portion of the interlayer dielectric layer not overlapping a region where the active layer is located is etched to form a groove, wherein an orthographic projection of the groove on the base substrate does not overlap an orthographic projection of the active layer on the base substrate. Specifically, the portion of the interlayer dielectric layer not overlapping the region where the active layer is located is etched, and an etching depth d is controlled to be equal to a first thickness, wherein the first thickness is the sum of a thickness d1 of the buffer layer 3 at a position of the light shielding layer 2 and a thickness d2 of the active layer 4. Specifically, the orthographic projection of the groove on the base substrate and the orthographic projection of the active layer on the base substrate have a gap. Alternatively, the orthographic projection of the groove on the base substrate is in contact with the orthographic projection of the active layer on the base substrate.

S1052, a region of the interlayer dielectric layer where the groove is located and the buffer layer continue to be etched to expose a part of the light shielding layer, and a part of the interlayer dielectric layer other than the region of the groove is etched to expose at least a part of the active layer so as to form a through groove, wherein an orthographic projection of the through groove on the base substrate covers an orthographic projection of a part of the active layer on the base substrate and covers an orthographic projection of a part of the light shielding layer on the base substrate, and the through groove and the groove overlap at a region where the light shielding layer is located to form a sleeved hole.

Specifically, S1052 that the region of the interlayer dielectric layer where the groove is located and the buffer layer continue to be etched to expose a part of the light shielding layer, and a part of the interlayer dielectric layer other than the region of the groove is etched to expose at least a part of the active layer so as to form the through groove, includes: the region of the interlayer dielectric layer where the groove is located and the buffer layer continue to be etched to expose a part of the light shielding layer so as to form a first sub-through groove, and the part of the interlayer dielectric layer other than the region of the groove is etched to expose at least a part of the active layer to form a second sub-through groove, wherein the first sub-through groove and the second sub-through groove are connected, and an orthographic projection of the first sub-through groove on the base substrate is covered by the orthographic projection of the groove on the base substrate.

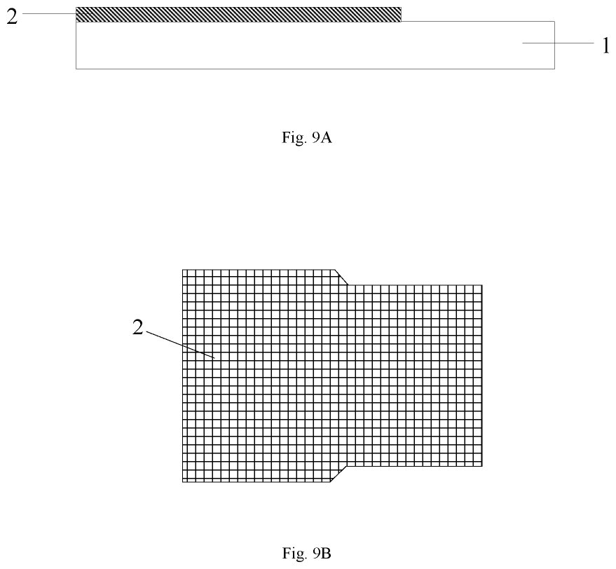

In order to understand the manufacturing method of the array substrate provided by the embodiment of the present disclosure more clearly, the manufacturing method of the array substrate provided by the embodiment of the present disclosure is further described in detail below in combination with FIG. 9A to FIG. 14B.

Step I, the light shielding layer 2 is formed on a side of the base substrate 1, as shown in FIG. 9A and FIG. 9B.

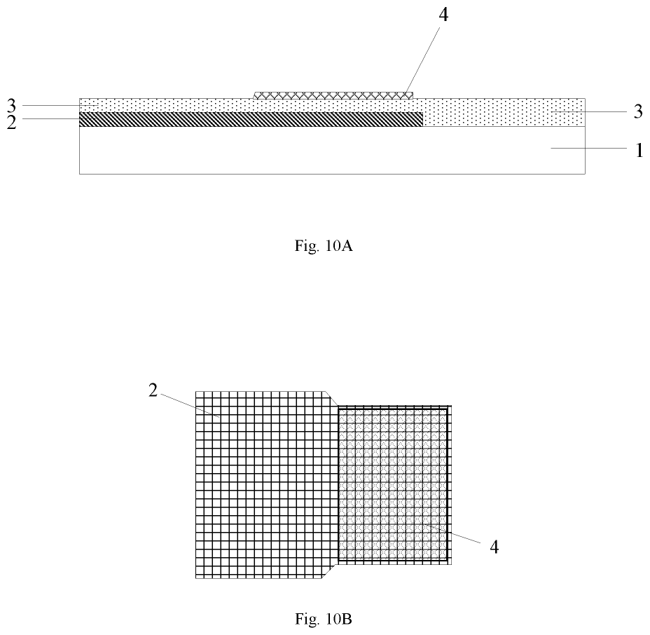

Step II, the buffer layer 3 is formed on a side of the light shielding layer 2 facing away from the base substrate 1, as shown in FIG. 10A.

Step III, the active layer 4 is formed on a side of the buffer layer 3 facing away from the light shielding layer 2, as shown in FIG. 10A and FIG. 10B.

Step IV, the interlayer dielectric layer 5 is formed on a side of the active layer 4 facing away from the buffer layer 3, as shown in FIG. 11.

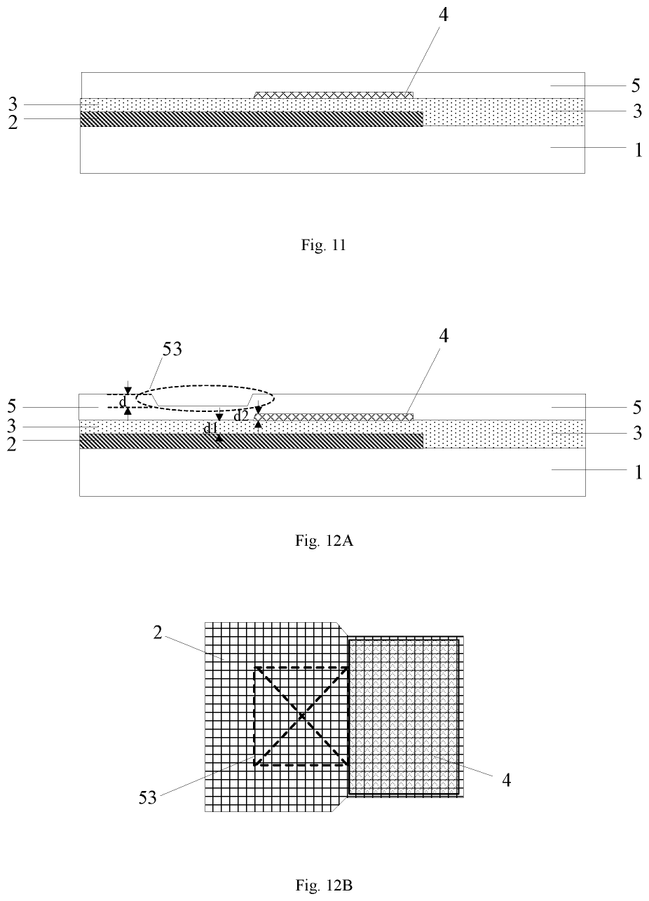

Step V, the portion of the interlayer dielectric layer 5 not overlapping the region where the active layer 4 is located is etched to form the groove 53, and an etching depth is controlled to be equal to the first thickness, wherein the first thickness is the sum of the thickness d1 of the buffer layer 3 at the position of the light shielding layer 2 and the thickness d2 of the active layer 4, as shown in FIG. 12A and FIG. 12B.

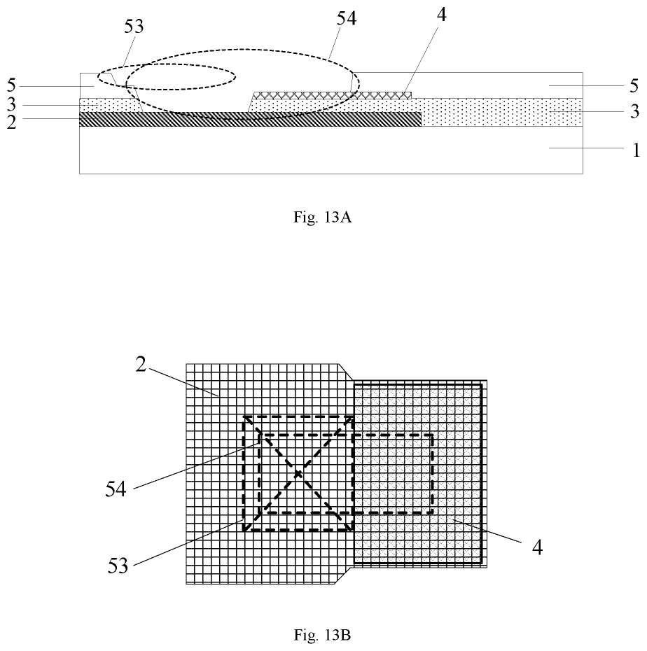

Step VI, the region of the interlayer dielectric layer 5 where the groove 53 is located and the buffer layer 3 continue to be etched to expose a part of the light shielding layer 2, and a part of the interlayer dielectric layer 5 other than the region of the groove 53 is etched to expose at least a part of the active layer 4 so as to form the through groove 54, as shown in FIG. 13A and FIG. 13B.

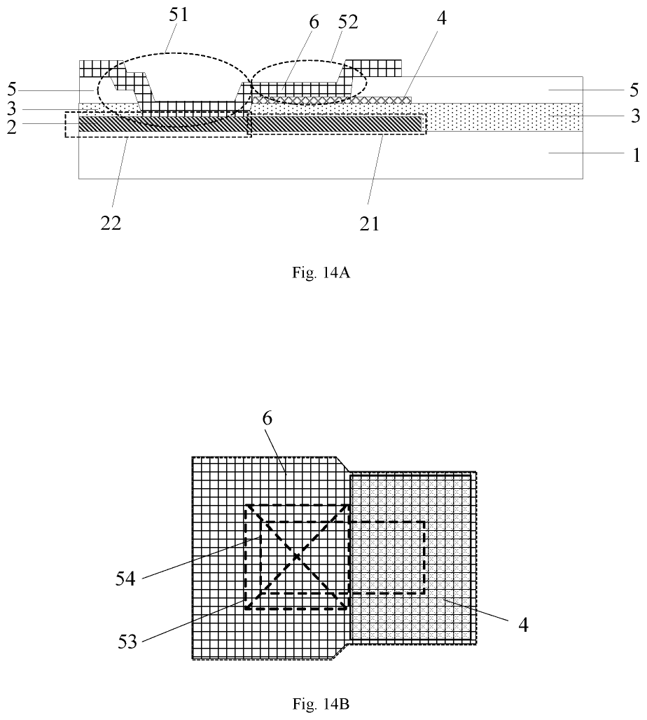

Step VII, the source drain layer 6 is formed on a side of the interlayer dielectric layer 5 facing away from the active layer, the source drain layer 6 covering the via hole, as shown in FIG. 14A and FIG. 14B.

The embodiments of the present disclosure have the following beneficial effects: the array substrate provided by the embodiment of the present disclosure includes: the base substrate; the light shielding layer, the buffer layer, the active layer and the interlayer dielectric layer, the interlayer dielectric layer has the via hole, the first part of the via hole penetrates through the interlayer dielectric layer and the buffer layer and exposes a part of the light shielding layer, the second part of the via hole penetrates through the interlayer dielectric layer and exposes at least a part of the active layer, and the source drain layer is electrically connected with the active layer and the light shielding layer through the via hole, that is, by arranging one via hole, while exposing the light shielding layer, the via hole further exposes the active layer, and finally the light shielding layer and the active layer may be connected through the source drain layer via the via hole; and compared with the prior art that when the light shielding layer and the active layer are connected through the two independent via holes, since each via hole has a minimum dimension limit and a certain distance is required between the two via holes, a large region for punching is required when the light shielding layer and the active layer are connected, according to the connecting manner provided by the embodiment of the present disclosure, the light shielding layer and the active layer may be connected through one via hole, and in the case that the via hole needs the same minimum dimension, in the embodiment of the present disclosure, a region required for connecting the active layer and the light shielding layer is smaller, thereby solving the problems in the prior art that an array substrate is larger in number of circuits, a region needed for punching is larger, and a high pixel resolution cannot be achieved easily.

Apparently, those skilled in the art can make various modifications and variations to the present disclosure without departing from the spirit and scope of the present disclosure. In this way, if these modifications and variations of the present disclosure fall within the scope of the claims of the present disclosure and equivalent technologies thereof, the present disclosure is also intended to include these modifications and variations.

1. An array substrate, comprising:
a base substrate;
a light shielding layer, located on a side of the base substrate;
a buffer layer, located on a side of the light shielding layer facing away from the base substrate;
an active layer, located on a side of the buffer layer facing away from the light shielding layer, an orthographic projection of the active layer on the base substrate being covered by an orthographic projection of the light shielding layer on the base substrate;
an interlayer dielectric layer, located on a side of the active layer facing away from the buffer layer, the interlayer dielectric layer having a via hole, the via hole comprising a first part and a second part, an orthographic projection of the first part on the base substrate being in contact with an orthographic projection of the second part on the base substrate, the first part of the via hole penetrating through the interlayer dielectric layer and the buffer layer and exposing a part of the light shielding layer, and the second part penetrating through the interlayer dielectric layer and exposing at least a part of the active layer; and
a source drain layer, located on a side of the interlayer dielectric layer facing away from the active layer, the source drain layer being electrically connected with the light shielding layer through the first part, and being electrically connected with the active layer through the second part.

2. The array substrate according to claim 1, wherein the interlayer dielectric layer has a step structure on a side wall facing the first part, and an orthographic projection of the step structure on the base substrate is a semi-closed frame pattern.

3. The array substrate according to claim 2, wherein a center of the orthographic projection of the step structure on the base substrate does not overlap a center of a first region, and the first region is a region of the light shielding layer exposed by the first part.

4. The array substrate according to claim 2, wherein the step structure comprises: a first inclined surface connected with a surface of the interlayer dielectric layer facing away from the buffer layer, a second inclined surface connected with a surface of the interlayer dielectric layer facing the buffer layer, and a plane connecting the first inclined surface with the second inclined surface; and
the buffer layer has a third inclined surface on a side wall facing the first part; and the second inclined surface and the third inclined surface are located on a same inclined surface.

5. The array substrate according to claim 1, wherein the orthographic projection of the active layer on the base substrate is in contact with the orthographic projection of the first part on the base substrate.

6. The array substrate according to claim 1, wherein the orthographic projection of the active layer on the base substrate and the orthographic projection of the first part on the base substrate have a gap therebetween.

7. The array substrate according to claim 1, wherein a material of the active layer comprises a semiconductor oxide.

8. The array substrate according to claim 1, wherein a depth of the via hole at a position exposing the light shielding layer is 5000 Å to 16000 Å.

9. The array substrate according to claim 8, wherein a depth of the via hole at a position exposing the active layer is 4000 Å to 12000 Å.

10. The array substrate according to claim 1, wherein an angle of gradient of the via hole is 40° to 80°.

11. The array substrate according to claim 1, wherein the array substrate comprises a driving transistor, and the source drain layer is a source drain layer of the driving transistor.

12. The array substrate according to claim 1, wherein a material of the light shielding layer is metal.

13. A display panel, comprising an array substrate, wherein the array substrate comprises:
a base substrate;
a light shielding layer, located on a side of the base substrate;
a buffer layer, located on a side of the light shielding layer facing away from the base substrate;
an active layer, located on a side of the buffer layer facing away from the light shielding layer, an orthographic projection of the active layer on the base substrate being covered by an orthographic projection of the light shielding layer on the base substrate;
an interlayer dielectric layer, located on a side of the active layer facing away from the buffer layer, the interlayer dielectric layer having a via hole, the via hole comprising a first part and a second part, an orthographic projection of the first part on the base substrate being in contact with an orthographic projection of the second part on the base substrate, the first part of the via hole penetrating through the interlayer dielectric layer and the buffer layer and exposing a part of the light shielding layer, and the second part penetrating through the interlayer dielectric layer and exposing at least a part of the active layer; and
a source drain layer, located on a side of the interlayer dielectric layer facing away from the active layer, the source drain layer being electrically connected with the light shielding layer through the first part, and being electrically connected with the active layer through the second part.

14. A display apparatus, comprising the display panel according to claim 13.

15. A manufacturing method of an array substrate, comprising:
forming a light shielding layer on a side of a base substrate;
forming a buffer layer on a side of the light shielding layer facing away from the base substrate;
forming an active layer on a side of the buffer layer facing away from the light shielding layer;
forming an interlayer dielectric layer on a side of the active layer facing away from the buffer layer;
by punching on a side of the interlayer dielectric layer facing away from the active layer, forming a first part of a via hole penetrating through the interlayer dielectric layer and the buffer layer and exposing a part of the light shielding layer, and forming a second part of the via hole penetrating through the interlayer dielectric layer and exposing at least a part of the active layer, an orthographic projection of the first part on the base substrate being in contact with an orthographic projection of the second part on the base substrate; and
forming a source drain layer on a side of the interlayer dielectric layer facing away from the active layer, the source drain layer covering the via hole, being electrically connected with the light shielding layer through the first part, and being electrically connected with the active layer through the second part.

16. The manufacturing method according to claim 15, wherein the, by punching on a side of the interlayer dielectric layer facing away from the active layer, forming a first part of a via hole penetrating through the interlayer dielectric layer and the buffer layer and exposing a part of the light shielding layer, and forming a second part of the via hole penetrating through the interlayer dielectric layer and exposing at least a part of the active layer, comprise:
etching a portion of the interlayer dielectric layer not overlapping a region where the active layer is located to form a groove, wherein an orthographic projection of the groove on the base substrate does not overlap an orthographic projection of the active layer on the base substrate; and
continuing to etch a region of the interlayer dielectric layer where the groove is located and the buffer layer to expose a part of the light shielding layer, and etching a part of the interlayer dielectric layer other than the region of the groove to expose at least a part of the active layer so as to form a through groove, wherein an orthographic projection of the through groove on the base substrate covers an orthographic projection of a part of the active layer on the base substrate and covers an orthographic projection of a part of the light shielding layer on the base substrate, and the through groove and the groove overlap at a region where the light shielding layer is located to form a sleeved hole.

17. The manufacturing method according to claim 16, wherein the continuing to etch a region of the interlayer dielectric layer where the groove is located and the buffer layer to expose a part of the light shielding layer, and etching a part of the interlayer dielectric layer other than the region of the groove to expose at least a part of the active layer so as to form a through groove, comprises:
continuing to etch the region of the interlayer dielectric layer where the groove is located and the buffer layer to expose a part of the light shielding layer so as to form a first sub-through groove, and etching the part of the interlayer dielectric layer other than the region of the groove to expose at least a part of the active layer to form a second sub-through groove, wherein the first sub-through groove and the second sub-through groove are connected, and an orthographic projection of the first sub-through groove on the base substrate is covered by the orthographic projection of the groove on the base substrate.

18. The manufacturing method according to claim 16, wherein the etching a portion of the interlayer dielectric layer not overlapping a region where the active layer is located, comprises:
etching the portion of the interlayer dielectric layer not overlapping the region where the active layer is located, and controlling an etching depth to be equal to a first thickness, wherein the first thickness is a sum of a thickness of the buffer layer at a position of the light shielding layer and a thickness of the active layer.

19. The manufacturing method according to claim 16, wherein the orthographic projection of the groove on the base substrate and the orthographic projection of the active layer on the base substrate have a gap.

20. The manufacturing method according to claim 16, wherein the orthographic projection of the groove on the base substrate is in contact with the orthographic projection of the active layer on the base substrate.
